(19) United States
(12) Patent Application Publication
(10) Pub. No.: US 2008/0174980 A1
(43) Pub. Date: Jul. 24, 2008

(54) QUICK-ACTION CLAMPING HOLDER FOR ELECTRONIC OR OPTOELECTRONIC DEVICES

(76) Inventors: Harro Krispin, Berlin (DE); Jochen Steininger, Berlin (DE); Tilo Wuensche, Potsdam (DE)

Correspondence Address: HOFFMAN WARNICK LLC, 75 STATE STREET, 14TH FLOOR, ALBANY, NY, 12207, US

(21) Appl. No.: 12/015,697

(22) Filed: Jan. 17, 2008

(30) Foreign Application Priority Data
Jan. 18, 2007 (DE) 20 2007 000 779.5

(51) Int. Cl. H05K 7/02

(52) U.S. Cl. 361/809

(57) ABSTRACT

The invention relates to a quick-action clamping holder for electronic or optoelectronic devices, particularly optoelectronic sensors, the housing of which has a external profile. The quick-action clamping holder has a body to be fitted at a holding location and at least one fixing arm, which can be pivoted from an open position into a closed position. In the closed position a device to be held is held with respect to the body by a back-gripping clamping engagement of the fixing arm with the external profile of the device. An actuating means is also provided for the manual actuation of the fixing arm. Furthermore, there is a spring means for pressing the fixing arm into the closed position or open position and that a locking means is provided for locking the fixing arm in the position where the latter is not forced or pressed by the spring means.

### FIELD OF THE INVENTION

The present invention relates to a quick-action clamping holder for electronic or optoelectronic devices, particularly optoelectronic sensors, the housing of which has a external profile, according to the preamble of claim 1.

### RELATED ART

Such a quick-action clamping holder is described in EP 1 492 977 B1 and has a body to be fitted at a holding location and at least one fixing arm, which can be pivoted from an open position into a closed position. The body can also be described as a basic body. In the closed position a device to be held is held with respect to the body or basic body by a back-gripping clamping engagement of the fixing arm with the external profile of the device. An actuating means is also provided for the manual actuation of the fixing arm.

In the case of optical and optoelectronic applications, e.g. light curtains or light screens, a basic problem is to fit optoelectronic components, particularly optoelectronic sensors, in clearly defined positions. For maintenance, cleaning or repair purposes such optoelectronic sensors must be removed and then refitted at the same clearly defined locations. For this purpose the prior art only discloses holding devices which are comparatively complicated to operate, i.e. to open and close again.

### SUMMARY OF THE INVENTION

The object of the invention is to provide a holder for electronic or optoelectronic devices, which can be particularly simply operated.

This object is achieved by the quick-action clamping holder having the features of claim 1. Preferred embodiments form the subject matter of the dependent claims.

The quick-action clamping holder of the aforementioned type is inventively further developed in that there is a spring means for pressing the fixing arm into the closed position or open position and that a locking means is provided for locking the fixing arm in the position where the latter is not forced or pressed by the spring means.

The essence of the invention is to firstly improve the security of operation compared with EP 1 492 977 B1 through a spring means, which presses the fixing arm into the closed or open position.

Another essential idea of the invention is to provide a locking means to be operated manually by an operator for locking the fixing arm. This greatly simplifies the operation of the quick-action clamping holder, because an operator can manually remove and then reinstall a device to be installed or held with respect to the holding location without the aid of any further tools.

Together with the back gripping engagement of the fixing arm with the external profile of the device to be held, it is possible in this way to bring about a very stable holding in a clearly defined position.

A vital advantage of the inventive concept is that apart from the rapid installation of the device in toolless manner, also a clearance-free fixing and one-handed operation are made possible.

In a particularly preferred variant the fixing arm is pivotably mounted in the body. In this embodiment the number of parts can be reduced.

Fundamentally several fixing arms can be provided which, in the closed state, in each case engage with corresponding profilings of the device. In a simple variant an appropriate abutment is formed on the body and the fixing arm presses the device to be held against said abutment. In this case, a profiling of the housing of the device can be brought into back-gripping engagement with the abutment. In these embodiments a particularly rapid clamping, secure holding and easy installation by the user are possible.

In further preferred variants the body is essentially constituted by a piece of a cut-to-length basic profile. This in particular leads to cost advantages during manufacture. Moreover, the fixing arm can essentially be made from a cut-to-length piece of a second profile material.

The basic profile and/or the second profile material are preferably aluminium continuously cast profiles, which are inexpensively obtainable in the desired form.

An easy installation of the body at the desired installation location is possible if in said basic profile are formed grooves for the easy positioning of a drill for making fixing holes. The fixing holes can be freely selected at the installation location in the longitudinal direction of said grooves.

The formation of the body and the fixing arm or optionally several fixing arms from aluminium profiles also makes it possible to provide further functional components of the inventive quick-action clamping holder directly in and with the aluminium profile.

Thus, e.g. in a preferred variant, which is characterized by ease of operation and good stability, the arresting means is in particular a locking lever, to be operated with one hand and having a locking profiling, which can be engaged with corresponding profiling on the fixing arm.

Such a locking lever can be formed in an aluminium basic profile as a resilient, tongue-shaped extension.

However, there can also be appropriate contourings for fitting the spring means in the body. In a preferred and easily produced variant, the spring means are constituted by a helical spring, which is in particular inserted between the basic profile and the second profile material from which the fixing arm is formed.

In place of the above-described locking of the open position with the aid of a suitable locking lever, the locking lever can also be constituted by a manually operable screw, particularly a knurled-head screw or a thumb screw.

There is no need for a separate spring, e.g. a separate helical spring in the case of variants where the fixing arm is inherently resilient. Such a fixing arm can e.g. be in the form of a resiliently positioned profile lug or profile tongue.

In further advantageous variants of the invention the locking means are formed by a second spring means, which presses the fixing arm into the open position. In such variants the functionality of the spring means and locking means is fulfilled by the same components.

The spring means can e.g. have a hinge connection, which on moving beyond a pressure point snaps round. Such variants are characterized by particularly easy operability, because little force has to be expended.

In particular the hinge connection can have two external hinges more particularly connected to two facing fixing arms, and also an inner hinge, which is connected to the two outer hinges. For opening and closing the quick-action clamping holder the inner hinge is then essentially extracted or forced through and in each case a pressure point must be overcome and on either side thereof the mechanical arrangement to a certain extent presses into the open or closed position.

Another preferred variant characterized by easy, low-force operation is characterized in that the actuating means are constituted by an actuating lever which, whilst overcoming a pressure point, is able to bring the inner hinge into a closed position and into an open position.

In a particularly preferred and even more easily operable variant of the inventive quick-action clamping holder the hinge connection can be brought into the closed position by pressing the device to be held into the quick-action clamping holder and can be brought into the open position by simply extracting the device. For this purpose the quick-action clamping holder does not have to be contacted by the user and instead only the device to be held is pressed in or removed.

In an alternative variant the spring means can also be constituted by an eccentric profile formed on an actuating lever which, beyond a pressure point, presses the fixing arm into the closed position. As both the open and closed position are mechanically stable, also this variant can be implemented by the user with limited force expenditure.

### BRIEF DESCRIPTION OF THE DRAWINGS

Further advantages and features of the invention are described hereinafter relative to the attached drawings, wherein show:

FIGS. 1 to 3: a first embodiment of the inventive quick-action clamping holder;

FIGS. 4 and 5: a second embodiment of the inventive quick-action clamping holder;

FIGS. 6 and 7: a third embodiment of the inventive quick-action clamping holder;

FIGS. 8 and 9: a fourth embodiment of the inventive quick-action clamping holder; and

FIGS. 10 and 11: a fifth embodiment of the inventive quick-action clamping holder.

### DETAILED DESCRIPTION OF THE INVENTION

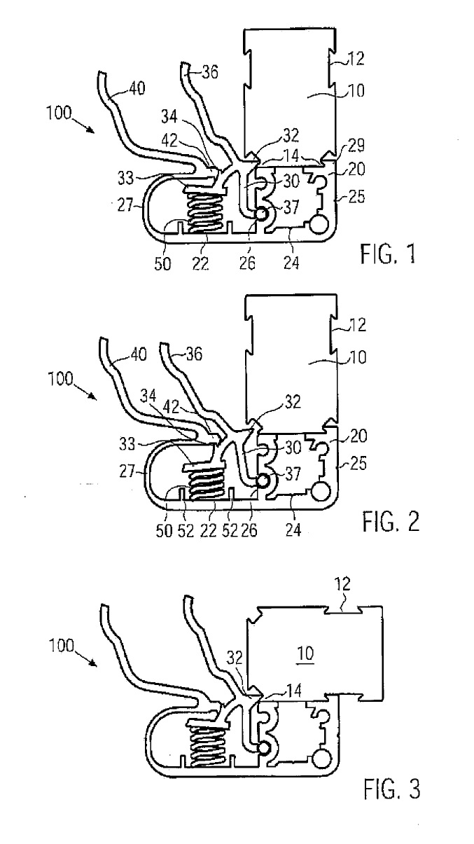

A first embodiment of the quick-action clamping holder according to the invention is explained relative to FIGS. 1 to 3.

The quick-action clamping holder 100 thereof has as essential components a body 20 made from an aluminium continuously cast profile, a fixing arm 30, a locking lever 40 and a helical screw 50. The quick-action clamping holder 100 is used for holding a here diagrammatically shown optoelectronic sensor 10, whose housing 12 has an outer contour 14 with profilings.

The fixing arm 30 is also made from an aluminium continuously cast profile and has a tongue or lug-like actuating lever 36, a profiling 32 for engaging in the outer profile 14 of the device 10 to be held and also a lever support 33 for the helical spring 50. On the fixing arm 30 is also formed a toroidal thickening 37 with which the fixing arm is pivotably mounted in a correspondingly shaped contour 26 in the basic profile. The locking lever 40 as a tongue or lug-like extension constitutes a part of the basic profile 20 and by means of an arcuate area 27 is resiliently mounted against a rear side of the fixing arm 30. For the locking engagement of the locking lever 40 relative to the fixing arm 30, said locking lever 40 has a locking profiling 42 and correspondingly on the rear side of fixing arm 30 is formed a locking profiling 34.

For mounting the spring 50 the basic profile 20 also has a pin 22 on which is mounted the spring 50. In order to avoid an undesired position change of spring 50, there are also profile tongues 52 in the basic profile 20.

The holder 100 makes it possible to bring about the one-handed fixing of the device 10 to be held with a defined external profile 14 with the aid of the contour or locking profiling 32 on fixing arm 30 and by the tension of spring 50 on lever support 33. Through the actuation of actuating lever 36 on fixing arm 30, which has its fulcrum with the radius contour 37 in the corresponding groove 26 in the basic profile, which can in particular be a ¾ cylinder groove, the spring 50 is tensioned until the locking profiling 34, which can also be called a hook contour, engages on the fixing arm 30 behind the profiling 42 of locking lever 40 and blocks the fixing arm 30 in the open position. Thus, the quick-action clamping holder 100 is opened and the device 10 can be removed. For holding or fixing the device 10, it is pressed in the desired direction into the quick-action clamping holder 100 and then the locking lever 40 is forced away from the actuating lever 36 of fixing arm 30 until the hook contour 34 is disengaged from the hook contour 42. By means of the lever support 33, the spring 50 then clamps the actuating lever with its locking profiling 32 against the corresponding outer contour 14 of device 10, which is forced against an abutment 29 formed on body 20.

The fixing in the longitudinal direction of fixing lever 30 in the cylinder groove 26 of the basic profile can take place by the installation of clamping pins, not shown in the drawings, at the ends of cylinder groove 26. Therefore the fixing arm 30 is shorter by two clamping pin lengths than the basic profile 20.

For positioning a drill on making the fixing holes in the longitudinal direction for the installation of the basic profile 20 at a holding location, the V-grooves 24, 25 are provided.

FIG. 1 shows the quick-action clamping holder 100 according to the invention in a front view and in the closed position. The cross-section of the housing 12 of the device 10 to be held, apart from the already described external contour 14, essentially has a rectangular shape. FIGS. 1 and 2 show a holding variant in which the narrow side of housing 12 abuts on body 20. FIG. 2 shows the quick-action clamping holder 100 in the open position, the fixing arm 30 being drawn rearwards and held in this location, counter to the tension of helical spring 50, with the aid of the locking lever. The user can remove the device 10 in the situation shown in FIG. 2.

FIG. 3 shows a holding variant in which the device 10 to be held abuts with part of its wider side on basic profile 20. Such holding variants require a corresponding contouring of the housing 12 of device 10.

The positioning shown in FIGS. 1 and 2 can also be called a 180° position and, corresponding to the variant shown in FIG. 3 can also be called a 90° position.

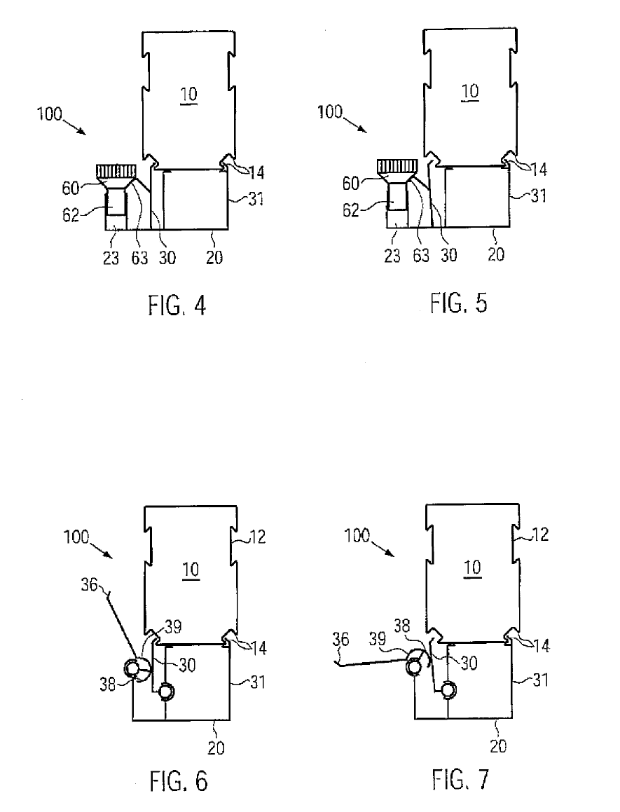

Further embodiments are described with reference to FIGS. 4 to 11, equivalent components in the drawings in each case carrying the same reference numerals.

In the case of the variant diagrammatically shown in FIGS. 4 and 5 the basic profile 20 has two fixing arms 30, 31, which are in each case essentially formed in one piece with the basic profile 20. By back-gripping engagement of the fixing arms 30, 31 with the external profile 14 of housing 10 the latter is held on the basic profile. At least the left-hand fixing arm 30 in FIGS. 4 and 5 is resiliently movable relative to the remaining basic profile 20. By means of a manually operable knurled-head screw 60, which abuts on a lever 63 formed on the left-hand fixing arm 30, the latter can be forced from an open position shown in FIG. 5 into a closed position shown in FIG. 4. This takes place by inserting the knurled-head screw 60, which is here in the form of a countersunk screw and has a self-shaping thread 62, in a groove 23 of the basic profile. Screw 60 presses with a 45° conical face against lever 63, whose end is provided with a radius contour, and presses the fixing arm 30 into external profile 14 of the device 10 to be held and fixes the same in clearance-free manner. On loosening the knurled-head screw 60, as a result of spring or resilient action the fixing arm 30 returns to its starting position, as shown in FIG. 5, and releases the devices to be held.

FIGS. 6 and 7 show a variant of the inventive quick-action clamping holder, in which a fixing arm 30 can be brought with the aid of an eccentric or cam 38, 39 on an actuating lever into the closed position. Here the basic profile has a right-hand fixing arm 31 which, if it is not movable against the basic profile 20, can also be referred to as a stop or abutment, as well as a left-hand, pivotably mounted fixing arm 30. On an actuating arm 36 is provided an eccentric profile or eccentric contour 38, 39, the fixing arm 30 and eccentric lever or actuating arm 36 with their respective radius contour in a correspondingly shaped 270° cylinder contour have their fulcrum. The fixing arm 30 can also be formed in basic profile 20. On forcing down the actuating arm 36 the eccentric contour 38, 39 presses lever 30 against the external profile 14 of the device 10 to be held and firmly clamps the latter in the holder. On passing beyond the radius maximum on external contour 38, 39 it is secured in the closed position and an additional securing action can be provided by spring and/or locking elements. By forcing or pulling up the handle 36 the eccentric 38, 39 once again exceeds its curve maximum and the lever 30 is released from the external profile 14 of the device 10 to be held. The open position is shown in FIG. 7.

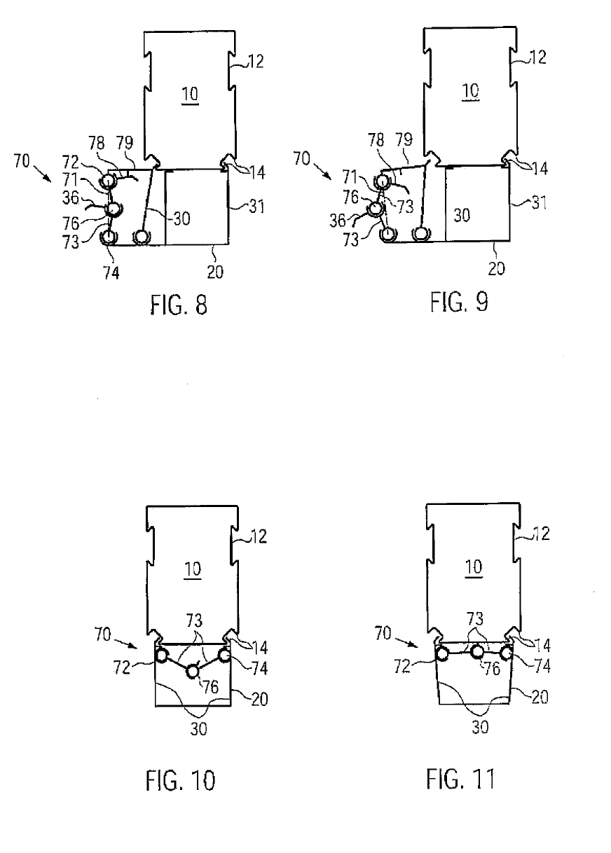

FIGS. 8 and 9 show a variant of the inventive quick-action clamping holder, in which the device 10 to be held is clamped according to the toggle lever principle. The fixing arm 30 with the aid of a hinge 70 acting as a spring means is forced into the outer contour 40 of the device 10 to be held. The hinge 70 has two external hinges 72, 74 and an inner hinge 76, which can be pressed inwards or drawn outwards with the aid of an actuating lever 36. The outer hinge 74 is connected by a web 73 to the inner hinge 76, which is in turn connected by a further web 73 to the further outer hinge 72. Fixing arm 30 is also connected by a web 79 to the outer hinge 72. By means of said web 79 the fixing arm 30 is pressed into the outer contour 14 of housing 10 by the webs 73 acting as a lever on forcing in or extracting the actuating lever 36. The closed position is reached when the handle 36 is drawn upwards or pressed inwards, so that a common fulcrum in the vicinity of the central hinge 76 assumes a position to the right of a centre axis 71 and therefore locks lever 30 in its closed position. By pressing the handle 36 downwards or pulling out the handle, the fulcrum in the vicinity of the central hinge 76 pivots to the left beyond the centre axis 71 and draws the lever 30 into the open position, as shown in FIG. 9. A lever 78 can serve as a stop.

A particularly preferred and easily functioning embodiment of the inventive quick-action clamping holder is described relative to FIGS. 10 and 11. This variant is also characterized by a simple, space-saving construction. Two fixing arms 30 are provided and can be forced apart with the aid of a hinge 70. Once again the hinge 70 comprises two outer hinges 72, 74, which are connected to the left and right-hand fixing arm 30. By means of webs 73 said outer hinges 72, 74 are connected to an inner hinge 76. The fixing arms 30 constitute part of an integral profile. If the hinge 70, which can also be called a toggle lever mechanism, is tensioned through the forcing up of the inner hinge 76, as shown in FIG. 10, there is an opening of the fixing arms 30, which can also be called here side walls of basic profile 20, so that they release the outer profile 14 of the device 10 to be held. By inserting device 10 in basic profile 20 it is moved beyond its pressure point and snaps back into the starting position, the hinge 70 or toggle lever mechanism opening and the side walls 30 of profile 20 once again clamp the outer contour 14 of the device to be held.

FIG. 11 shows the opened variant shortly prior to the pressing of the device 10 to be held into the closed position.

All the variant shown in FIGS. 4 to 11 also allow the fixing of the device 10 to be held in the 90° position, as shown in FIG. 3.

The present invention leads to a novel quick-action clamping holder for electronic and optoelectronic devices, particularly optoelectronic sensors, which has a simple construction and which can be particularly easily operated.

1. Quick-action clamping holder for electronic or optoelectronic devices, particularly optoelectronic sensors, the housing of which has an external profile,
with a body to be fitted at a holding location,
with at least one fixing arm, which can be pivoted from an open position into a closed position and in said closed position a device to be held is held by a back-gripping clamping engagement of the fixing arm with the external profile of the device on the body, and
with an actuating means for the manual actuation of the fixing arm,
wherein
there is a spring means for pressing the fixing arm into the closed position or the open position and
there is a locking means for locking the fixing arm in the position into which the fixing arm is not pressed by the spring means.

2. Quick-action clamping holder according to claim 1,
wherein
the fixing arm is pivotably mounted relative to the body.

3. Quick-action clamping holder according to claim 2,
wherein
an abutment is formed on the body.

4. Quick-action clamping holder according to claim 2,
wherein
an abutment is formed on the body and
the fixing arm forces the device to be held against the abutment.

5. Quick-action clamping holder according to claim 1,
wherein
the body is essentially made from one piece of a cut-to-length basic profile.

6. Quick-action clamping holder according to claim 1,
wherein
the body is essentially made from one piece of a cut-to-length basic profile and the fixing arm is essentially made from a cut-to-length piece of a second profile material.

7. Quick-action clamping holder according to claim 1,
wherein
the locking means is a manually operable locking lever with a locking profiling, which can be engaged with a corresponding profiling on fixing arm.

8. Quick-action clamping holder according to claim 7,
wherein
the locking lever is formed in the basic profile as a resilient, tongue-shaped extension.

9. Quick-action clamping holder according to claim 7,
wherein
the locking lever is a one-handed operable locking lever.

10. Quick-action clamping holder according to claim 1,
wherein
the locking means is formed by a second spring means, which presses the fixing arm into the open position.

11. Quick-action clamping holder according to claim 6,
wherein
at least one of the basic profile and the second profile material is an aluminium continuously cast profile.

12. Quick-action clamping holder according claim 6,
wherein
the spring means is a helical spring.

13. Quick-action clamping holder according to claim 6,
wherein
the spring means is a helical spring which is inserted between the basic profile and the second profile material.

14. Quick-action clamping holder according to claim 1,
wherein
the locking means is a manually operable screw.

15. Quick-action clamping holder according to claim 14,
wherein
the locking means is a screw selected from the group consisting of a knurled-head screw and a thumb screw

16. Quick-action clamping holder according to claim 5,
wherein
grooves are formed in the basic profile for the easy positioning of a drill for making fixing bore holes.

17. Quick-action clamping holder according to claim 1,
wherein
the fixing arm is inherently resilient.

18. Quick-action clamping holder according to claim 1,
wherein
the fixing arm is a resiliently positioned profile lug.

19. Quick-action clamping holder according to claim 1,
wherein
there are provided two facing fixing arms.

20. Quick-action clamping holder according to claim 1,
wherein
the spring means have a hinge connection, which on moving beyond a pressure point snaps round.

21. Quick-action clamping holder according to claim 1,
wherein
the spring means is provided by an eccentric profile formed on an actuating lever and which beyond a pressure point forces the fixing arm into the closed position.

22. Quick-action clamping holder according to claim 20,
wherein
the hinge connection has two outer hinges and an inner hinge connected to the two outer hinges.

23. Quick-action clamping holder according to claim 20,
wherein
the hinge connection has two outer hinges and an inner hinge connected to the two outer hinges and
the actuating means is an actuating lever with which, whilst overcoming a pressure point, can bring the inner hinge into a closed position and into an open position.

24. Quick-action clamping holder according to claim 20,
wherein
the hinge connection can be brought into the closed position by pressing the device into the quick-action clamping holder and can be brought into the open position by extracting the device.

25. Quick-action clamping holder according to claim 20,
wherein
the hinge connection has two outer hinges which are connected to fixing arms and an inner hinge connected to the two outer hinges.
